(19) United States
(12) Patent Application Publication
(10) Pub. No.: US 2008/0310653 A1
(43) Pub. Date: Dec. 18, 2008

(54) Digital audio signal amplifier

(76) Inventor: En-Min Jow, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/898,223

(22) Filed: Sep. 11, 2007

(30) Foreign Application Priority Data
Jun. 12, 2007 (TW) 96209650
Aug. 3, 2007 (TW) 96212802

(51) Int. Cl. H03F 21/00

(52) U.S. Cl. 381/120

(57) ABSTRACT

A digital audio signal amplifier includes: a digital signal amplifying module having a digital audio signal plug connected with a digital audio signal outlet of a main board to receive digital audio signals, the digital signal amplifying module processing the digital audio signals to generate high power analog audio signals; and an analog signal output interface coupled to the digital signal amplifying module and transferring the high power analog audio signals to a set of speaker.

### BACKGROUND OF THE INVENTION

1. Field of the Invention

The present invention relates to a signal amplifier, and more especially, to a digital signal amplifier which is used to provide the high power analog audio signals to the speaker.

2. Background of the Related Art

Because of the progress of the personal computer and the Internet development, the on-line game and the on-line multimedia emphasize the effects of the video and audio more and more. However, in the common computer, the built-in speaker is so rough and the sound quality is not good enough, and so as to affect the recreational effect of the on-line game or the on-line multimedia.

All the sound formats, such as the MIDI, WAVE, MP3, are digital format in the computer, and the music CD, VCD or DVD are also coded in digital formats, but the traditional speaker only can receive the analog signals before push sound waves. During the process of transforming the digital signals to the analog signals, the signals will decay and be interfered by the noise, and the voltage of the circuits in the computer case also reduce the sound quality and make the noise to the sound signal.

Recently, because the USB interface is supported by the computer system, the computer system can connect with many kinds of peripheral apparatuses by the USB interface instead of the additional connectors, and so as to increase the practicability of the small-scale computer system.

In the conventional USB digital speaker, which is connected to the USB port of the computer, the signal transformation is not proceeded in the computer case, so that the signal will not be seriously interfered and can have the high-quality digital audio signals, and to make the sound from the computer be clear, noiseless and real to have the different hearing feeling against the common speaker. However, an additional power line, which is required to satisfy the power demand of the speaker in order to provide the good sound, will cause the inconvenience of the usage of the speaker. In generally, a high quality speaker usually avoids the interference, which caused by the physical sound wave action, by separating the speaker apart from the component of the amplifier. Therefore, the foregoing conventional USB digital speaker cannot provide the best sound signals due to its integration of the speaker and the component of the amplifier.

### SUMMARY OF THE INVENTION

In order to solve the foregoing problems, one object of this invention is to provide a digital audio signal amplifier, wherein a digital signal amplifying module is used to receive, process and amplify the digital audio signals, so that the speaker can directly receive the high power analog audio signals and broadcast the stereo sounds.

One object of this invention is to provide a digital audio signal amplifier, which can be configured in the DVD projector, the video recorder, the mp3 player, the CD player or the computer, and can be connected with the USB interface, the Toshiba Link SONY/PHILIPS digital Interface (TOSLINK SPDIF), the RCA SPDIF or the I²S digital audio interface on the main board to directly amplify the digital audio signals.

Another object of this invention is to provide a portable digital audio signal amplifier, wherein a USB plug receives digital signals and voltage signals from a computing device. So the portable digital audio signal amplifier can use the voltage signals as a power without an external power supply.

Accordingly, one embodiment of the present invention provides a digital audio signal amplifier, which includes: a digital signal amplifying module having a digital audio signal plug connected with a digital audio signal outlet of a main board to receive a plurality of digital audio signals, wherein the digital signal amplifying module processes the plurality of digital audio signals to generate a plurality of high power analog audio signals; and an analog signal output interface having at least one analog audio connector, wherein the analog signal output interface is coupled to the digital signal amplifying module, so that the plurality of high power analog audio signals are transferred to the analog audio connector; wherein an exterior speaker set is connected with the analog audio connector by using at least one speaker line, to receive the plurality of high power analog audio signals and directly transform the plurality of high power analog audio signals to a plurality of continuous sound waves.

Another embodiment of the present invention provides a portable digital audio signal amplifier, which includes: a USB plug receiving digital signals from a computing device and outputting digital audio signals; a digital audio signal amplifying module coupled to the USB plug and receiving the digital audio signals, the digital signal amplifying module outputting high-power analog audio signals; and an analog signal output interface coupled to the digital signal amplifying module and outputting high-power analog audio signals to a set of speaker.

Another embodiment of the present invention provides a portable digital audio signal amplifier, which includes: an Inter-IC Sound interface plug receiving digital signals from a computing device and outputting digital audio signals; a digital audio signal amplifying module coupled to the Inter-IC Sound interface plug and receiving digital audio signals, the digital signal amplifying module outputting high-power analog audio signals; and an analog signal output interface, coupled to the digital signal amplifying module and outputting high-power analog audio signals to a speaker set.

### BRIEF DESCRIPTION OF THE DRAWINGS

FIG. 1 is a diagram illustrating the connecting structure of the digital audio signal amplifier in accordance with an embodiment of the present invention.

FIG. 2 is a diagram illustrating the portable digital audio signal amplifier in accordance with an embodiment of the present invention.

FIG. 3 is a diagram illustrating another portable digital audio signal amplifier in accordance with an embodiment of the present invention.

### DETAILED DESCRIPTION OF THE INVENTION

The present invention provides a digital audio signal amplifier, which is used to receive and process a plurality of digital audio signals and then output a plurality of high power analog audio signals to drive a set of speaker to create the sound wave. Accordingly, a speaker set can directly receive the output signals in the present invention to broadcast the stereo sound.

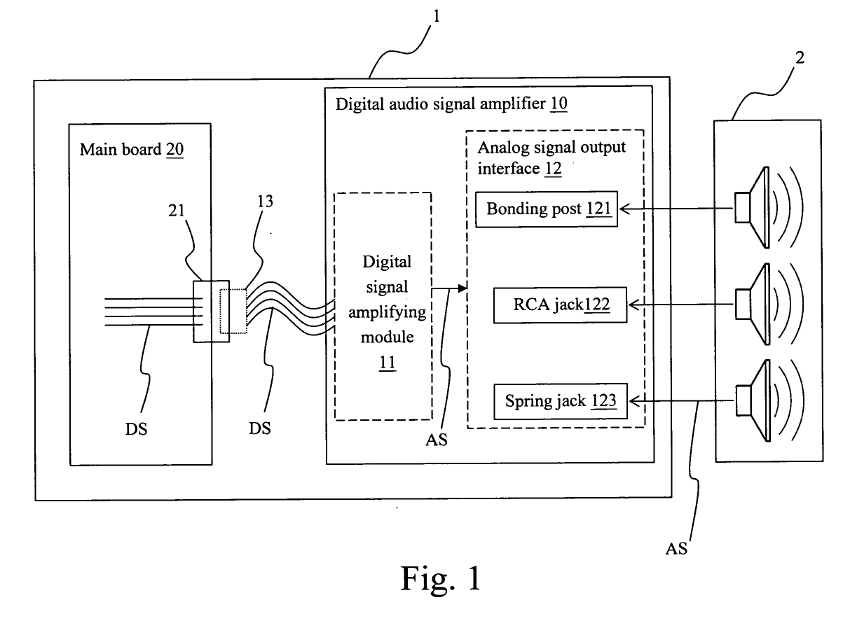

FIG. 1 is a diagram illustrating the connecting structure of the digital audio signal amplifier in accordance with an embodiment of the present invention. The digital audio signal amplifier 10 includes a digital signal amplifying module 11 and an analog signal output interface 12. The digital signal amplifying module 11 has a digital audio signal plug 13 connected with a digital audio signal outlet 21 of a main board 20 to receive a plurality of continuous digital audio signals (DS), and the digital signal amplifying module 11 is used to process and amplify the digital audio signals to generate the high power analog audio signals (AS). The analog signal output interface 12, which has a plurality of analog audio connectors, is coupled to the digital signal amplifying module 11, so that the high power analog audio signals (AS) are transferred to the analog audio connector. Wherein the analog audio connector includes a bonding post 121, a RCA jack 122 and a spring jack 123, which are directly connected with the speakers for outputting the sound.

Accordingly, the digital signal amplifying module 11 and the analog signal output interface 12 are integrated on a printed circuit board, and the digital audio signal plug 13 is used to connect with the digital audio signal outlet 21 of the main board 20. Therefore, the digital audio signal amplifier 10 and the main board 20 can simultaneously configured in an electronic apparatus 1, such as the DVD projector, the video recorder, the mp3 player, the CD player or any calculating machine with at least one processor.

Besides, the digital audio signal outlet 21 maybe the USB interface, the TOSLINK SPDIF, the RCA SPDIF or the I²S digital audio interface.

Accordingly, an exterior speaker set 2 is connected with the analog audio connector by using at least one speaker wire to receive the high power analog audio signals (AS) and directly transform the high power analog audio signals (AS) to the continuous sound waves.

In the present invention, the digital audio signals (DS) from the main board 20 of the electronic apparatus 1 are received by the digital signal amplifying module 11 directly, and are amplified to the high power analog audio signals (AS), which will then be output to the speaker set 2 to directly broadcast the stereo sound.

Besides, in one embodiment, when the digital audio signal outlet 21 is the USB interface and the output power of the digital signal amplifying module 11 is less than 2.5 W, the voltage signals of the USB can be received by the digital signal amplifying module 11 directly to as a power supply, and so that an additional power line is not required in the present invention. Furthermore, because the digital signal amplifying module 11 and the analog signal output interface 12 are integrated on one printed circuit board, the digital audio signal amplifier 10 can has small volume to be able to configure in any small-scale electronic apparatus.

In another embodiment, when the digital audio signal outlet 21 is the USB interface and the output power of the digital signal amplifying module 11 is more than 2.5 W, an additional power line is required by the digital audio signal amplifier 10 to provide the high power output.

Furthermore, when other digital audio signal outlet 21, such as the TOSLINK SPDIF, RCA SPDIF or the I²S digital audio interface, is used to connect the digital audio signal plug 13 of the digital signal amplifying module 11, an additional power line is required by the digital audio signal amplifier 10 to provide the operation power.

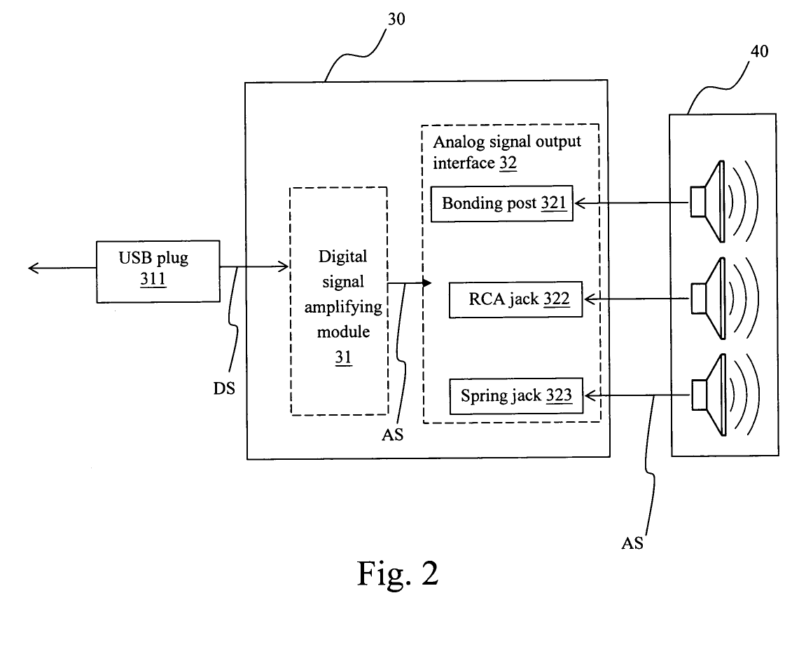

FIG. 2 is a diagram illustrating the portable digital audio signal amplifier in accordance with an embodiment of the present invention. The portable digital audio signal amplifier 30 has a USB plug 311 to receive digital signals from a computing device (not shown) and output digital audio signals (DS) which are transferred to a digital signal amplifying module 31 coupled to the USB plug 311. The digital signal amplifying module 31 processes those digital audio signals (DS) and then output high-power analog audio signals (AS) to an analog signal output interface 32, where a set of speaker 40 is plugged to and receives the high-power analog audio signals (AS).

Accordingly, digital signal amplifying module 31 directly receives digital signals from a computing device, then amplifying and transforming the digital signals to speaker set 40 for audio sound effect. The computing device may be a PC or handheld computing device, like PDA or smart phone, for which only with a USB interface.

Furthermore, the USB plug plugs in the USB socket on the computing device and receives a voltage signal and transfers the voltage signal to the digital signal amplifying module 31 as a power supply. In that embodiment, the present invention does not need the power line. Besides, the digital signal amplifying module 31 and the analog signal output interface 32 are combined on a printed circuit board to cause the portable digital audio signal amplifier 30 has a small size for easy carry.

When the required power of output audio signal is more then 2.5 W, even using USB Interface still need a power supply line to get power to push the high power analog audio output.

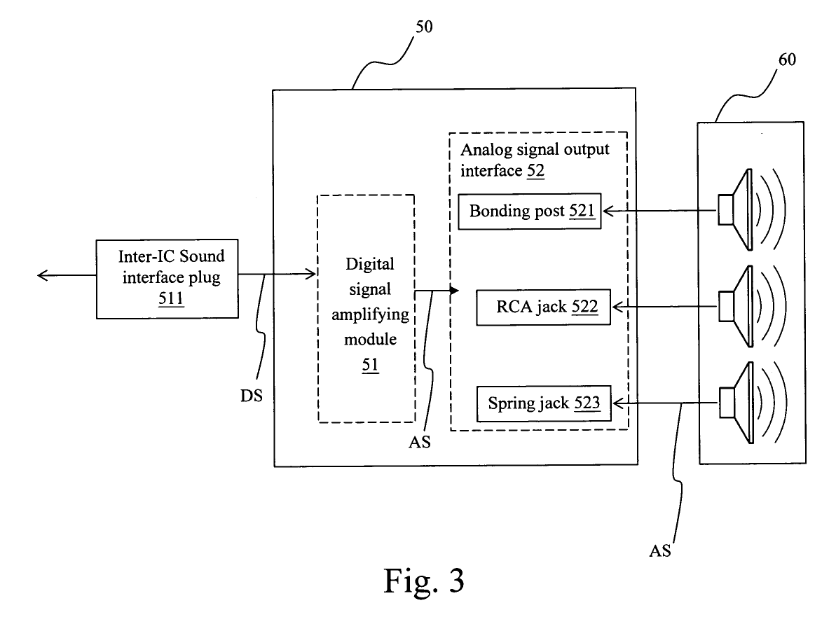

FIG. 3 is a diagram illustrating another portable digital audio signal amplifier in accordance with an embodiment of the present invention. The portable digital audio signal amplifier 50 includes: an Inter-IC Sound (I²C) interface plug 511 receiving digital signals from a computing device (not shown) and outputting digital audio signals (DS) to a module; a digital signal amplifying module 51 coupled to the Inter-IC Sound (I²C) interface plug 511 for receiving and processing digital audio signals (DS) and outputting high-power analog audio signals (AS); and an analog signal output interface 52 coupled to the digital signal amplifying module 51 and outputting high-power analog audio signals (AS) to a speaker set 60.

The analog signal output interface 52 can be a bonding post 121, a RCA jack 122 or a spring jack 123, which are directly connected with the speakers' wire for outputting the signals.

The portable digital audio signal amplifier as a single device can be carried conveniently. Especially with the USB connection, the device need not power supply line making the computing device easy to connect the speaker to play the sound.

To sum up, the present invention can receive the pure digital audio signals, process and amplify the digital audio signals to generate the high power analog audio signals to directly drive the speaker, and so that the speaker set directly receive the high power analog audio signals to provide the magnetic effect and vibrate to output ideal sound waves. Furthermore, when the USB interface receives the digital audio signals, the voltage signals are received simultaneously to start the amplifying of the digital audio signals.

Although the present invention has been explained in relation to its preferred embodiment, it is to be understood that other modifications and variation can be made without departing the spirit and scope of the invention as hereafter claimed.

What is claimed is:

1. a digital audio signal amplifier, comprising:
a digital signal amplifying module having a digital audio signal plug connected with a digital audio signal outlet of a main board to receive a plurality of digital audio signals, wherein said digital signal amplifying module processes said plurality of digital audio signals to generate a plurality of high power analog audio signals; and
an analog signal output interface having at least one analog audio connector, wherein said analog signal output interface is coupled to said digital signal amplifying module, so that said plurality of high power analog audio signals are transferred to said analog audio connector;
wherein an exterior speaker set is connected with said analog audio connector by using at least one speaker line, to receive said plurality of high power analog audio signals and directly transform said plurality of high power analog audio signals to a plurality of continuous sound waves.

2. The digital audio signal amplifier according to claim 1, wherein said digital audio signal outlet is a Toshiba Link SONY/PHILIPS digital Interface.

3. The digital audio signal amplifier according to claim 1, wherein said digital audio signal outlet is a RCA SONY/PHILIPS digital Interface.

4. The digital audio signal amplifier according to claim 1, wherein said digital audio signal outlet is an I²S digital audio interface.

5. The digital audio signal amplifier according to claim 1, wherein said analog audio connector comprises a bonding post, a spring jack and a RCA jack.

6. The digital audio signal amplifier according to claim 1, wherein said digital audio signal outlet is a USB interface.

7. The digital audio signal amplifier according to claim 6, wherein said digital signal amplifying module is further used to receive a plurality of voltage signals as a power supply.

8. The digital audio signal amplifier according to claim 7, wherein said plurality of voltage signals are input from said USB interface.

9. The digital audio signal amplifier according to claim 1, wherein said digital signal amplifying module and said analog signal output interface are combined on a printed circuit board.

10. a portable digital audio signal amplifier, comprising:
a USB plug, receiving digital signals from a computing device and outputting digital audio signals;
a digital audio signal amplifying module, coupled to said USB plug to receive said digital audio signals, and output high-power analog audio signals; and
an analog signal output interface, coupled to said digital signal amplifying module and outputting high-power analog audio signals to a set of speaker.

11. The portable digital audio signal amplifier according to claim 10, wherein said analog signal output interface comprises a bonding post, a spring jack and a RCA jack.

12. The portable digital audio signal amplifier according to claim 10, wherein said USB plug receives a voltage signal and transfers said voltage signal to said digital signal amplifying module.

13. The portable digital audio signal amplifier according to claim 10, wherein said digital signal amplifying module and said analog signal output interface are combined on a printed circuit board.

14. a portable digital audio signal amplifier, comprising:
an Inter-IC Sound interface plug, receiving digital signals from a computing device and outputting digital audio signals;
a digital audio signal amplifying module, coupled to said Inter-IC Sound interface plug and receiving digital audio signals, said digital signal amplifying module outputting high-power analog audio signals; and
an analog signal output interface, coupled to said digital signal amplifying module and outputting high-power analog audio signals to a speaker set.

15. The portable digital audio signal amplifier according to claim 14, wherein said analog signal output interface comprises a bonding post, a spring jack and a RCA jack.

16. The portable digital audio signal amplifier according to claim 14, wherein said digital signal amplifying module and said analog signal output interface are combined on a printed circuit board.
